(19) United States
(12) Patent Application Publication
(10) Pub. No.: US 2025/0031330 A1
(43) Pub. Date: Jan. 23, 2025

(54) Hinge Mechanism and Electronic Device

(71) Applicant: Huawei Technologies Co., Ltd., Shenzhen (CN)

(72) Inventors: Tuo Shi, Shanghai (CN); Qiang Zhan, Dongguan (CN)

(21) Appl. No.: 18/898,105

(22) Filed: Sep. 26, 2024

Related U.S. Application Data
(63) Continuation of application No. PCT/CN2024/079422, filed on Feb. 29, 2024.

(30) Foreign Application Priority Data
Jul. 20, 2023 (CN) 202310898042.0

(51) Int. Cl. H05K 5/02; E05D 3/12; E05D 11/06; F16C 11/04; G06F 1/16

(52) U.S. Cl. CPC H05K 5/0226; F16C 11/04; G06F 1/1652; G06F 1/1681; E05D 3/122; E05D 11/06

(57) ABSTRACT

A hinge mechanism includes a main shaft, a first housing support, a second housing support, and a flatness stop mechanism. The flatness stop mechanism includes a first stop structure and a second stop structure. The first stop structure includes a first connecting rod and a first stop block, where the first connecting rod is rotatably coupled to the main shaft, the first connecting rod is slidably coupled to the first housing support, the first stop block is fastened to the first housing support, and the first stop block is disposed opposite to the first connecting rod. The second stop structure includes a second connecting rod and a second stop block.

### CROSS-REFERENCE TO RELATED APPLICATIONS

This is a continuation of International Patent Application No. PCT/CN2024/079422 filed on Feb. 29, 2024, which claims priority to Chinese Patent Application No. 202310898042.0 filed on Jul. 20, 2023. The disclosures of the aforementioned applications are hereby incorporated by reference in their entireties.

### BACKGROUND

An included angle of a foldable electronic device in a flattened state is very important for fineness of the device. Usually, an included angle of an existing foldable electronic device in a flattened state is controlled based on a thickness size of a stop plane between rotational fitting parts, for example, a thickness size of a stop plane between an arc arm of a hinge and a main shaft. However, a size and a fitting tolerance of the rotational fitting part are large, and reliability of control of the included angle in the flattened state is low. Therefore, the foldable electronic device is likely to be over-folded, and a flexible display of the foldable electronic device is likely to be damaged.

### SUMMARY

This disclosure provides a hinge mechanism and an electronic device, to resolve a problem of low reliability of control of an included angle of a foldable electronic device in a flattened state.

According to a first aspect, this disclosure provides a hinge mechanism. The hinge mechanism may be used in a foldable electronic device, where the hinge mechanism is disposed opposite to a foldable part of a flexible display of the electronic device, and the electronic device is unfolded or folded by using the hinge mechanism. The hinge mechanism may include a main shaft, a first housing support, a second housing support, and a flatness stop mechanism, where the first housing support and the second housing support may be respectively disposed on two opposite sides of the main shaft, and the flatness stop mechanism may include a first stop structure and a second stop structure. The first stop structure may include a first connecting rod and a first stop block, the first connecting rod may be rotatably connected to the main shaft, the first connecting rod may be slidably connected to the first housing support, the first stop block may be fastened to the first housing support, and the first stop block is disposed opposite to the first connecting rod. The second stop structure may include a second connecting rod and a second stop block, where the second connecting rod may be rotatably connected to the main shaft, the second connecting rod may be slidably connected to the second housing support, the second stop block may be fastened to the second housing support, and the second stop block is disposed opposite to the second connecting rod. The first connecting rod may be in transmission connection to the second connecting rod. When the electronic device is unfolded or folded, the first housing support and the second housing support may rotate synchronously away from or close to each other relative to the main shaft, and the first connecting rod and the second connecting rod may rotate synchronously away from or close to each other relative to the main shaft. The first connecting rod may slide relative to the first housing support, and the second connecting rod may slide relative to the second housing support. In a process in which the electronic device is unfolded to a flattened state, the first connecting rod may slide in a direction away from the first housing support, and the second connecting rod may slide in a direction away from the second housing support. When the electronic device is unfolded to the flattened state, the first connecting rod may press against the first stop block, and the second connecting rod may press against the second stop block. In this way, the first connecting rod and the second connecting rod are prevented from respectively sliding in directions away from the first housing support and the second housing support.

In the technical solution provided in this disclosure, in a process in which the electronic device is unfolded to the flattened state, the first connecting rod slides in a direction away from the first housing support, and when the electronic device is unfolded to the flattened state, the first connecting rod presses against the first stop block, so that the first connecting rod is restricted from continuously sliding relative to the first housing support, and the first housing support is restricted from continuously rotating in an unfolding direction relative to the main shaft. Similarly, the second connecting rod slides in a direction away from the second housing support, and when the electronic device is unfolded to the flattened state, the second connecting rod presses against the second stop block, so that the second connecting rod is restricted from continuously sliding relative to the second housing support, and the second housing support is further restricted from continuously rotating in the unfolding direction relative to the main shaft. Rotation of both the first housing support and the second housing support in the unfolding direction is restricted in the flattened state, so that an included angle of the electronic device in the flattened state can be reliably controlled, the electronic device is not likely to be over-folded, and the flexible display of the electronic device is not likely to be damaged.

In a specific implementable solution, a first sliding slot may be disposed on the first housing support, the first sliding slot may extend in a direction away from the main shaft, and the first connecting rod may be slidably disposed in the first sliding slot. When the electronic device is unfolded or folded, the first connecting rod may slide relative to the first housing support in the direction away from the first housing support or a direction close to the first housing support. In this way, the first connecting rod is slidably connected to the first housing support. A second sliding slot may be disposed on the second housing support, the second sliding slot may extend in a direction away from the main shaft, and the second connecting rod may be slidably disposed in the second sliding slot. When the electronic device is unfolded or folded, the second connecting rod may slide relative to the second housing support in the direction away from the second housing support or a direction close to the second housing support. In this way, the second connecting rod is slidably connected to the second housing support.

When the sliding slot is disposed, a first avoidance slot may be disposed in the first sliding slot, and the first avoidance slot may be disposed on a side wall that is of the first sliding slot and that is a direction perpendicular to a rotation axial direction of the hinge mechanism. The first avoidance slot may provide avoidance space for rotation that is of the first connecting rod relative to the first housing support and that may exist in a process in which the first connecting rod slides relative to the first housing support, to avoid interference to sliding of the first connecting rod. A second avoidance slot may be disposed in the second sliding slot, and the second avoidance slot may be disposed on a side wall that is of the second sliding slot and that is in the direction perpendicular to the rotation axial direction of the hinge mechanism. The second avoidance slot may provide avoidance space for rotation that is of the second connecting rod relative to the second housing support and that may exist in a process in which the second connecting rod slides relative to the second housing support, to avoid interference to sliding of the second connecting rod.

In a specific implementable solution, a first opening may be disposed in the first sliding slot in the direction perpendicular to the rotation axial direction of the hinge mechanism, the first stop block may cover the first opening, and a part of the first connecting rod may be located between the first stop block and the first housing support. The first stop block and the first housing support clamp a part of the first connecting rod, so that the first connecting rod can be stably maintained in the first sliding slot, and the first connecting rod can be prevented from shaking in the direction perpendicular to the rotation axial direction of the hinge mechanism. Therefore, sliding stability and smoothness of the first connecting rod are improved. A second opening may be disposed in the second sliding slot in the direction perpendicular to the rotation axial direction of the hinge mechanism, the second stop block may cover the second opening, and a part of the second connecting rod may be located between the second stop block and the second housing support. The second stop block and the second housing support clamp a part of the second connecting rod, so that the second connecting rod can be stably maintained in the second sliding slot, and the second connecting rod can be prevented from shaking in the direction perpendicular to the rotation axial direction of the hinge mechanism. Therefore, sliding stability and smoothness of the second connecting rod are improved.

In a specific implementable solution, a first concave part and a second concave part may be disposed in the first sliding slot, the first concave part and the second concave part may be respectively disposed on two side walls that are of the first sliding slot and that are opposite to each other in the rotation axial direction of the hinge mechanism, and the first connecting rod may be slidably connected to the first concave part and the second concave part. The first concave part and the second concave part may provide a sliding rail for sliding of the first connecting rod in the first sliding slot, so that sliding stability of the first connecting rod can be improved. A third concave part and a fourth concave part may be disposed in the second sliding slot, the third concave part and the fourth concave part may be respectively disposed on two side walls that are of the second sliding slot and that are opposite to each other in the rotation axial direction of the hinge mechanism, and the second connecting rod may be slidably connected to the third concave part and the fourth concave part. The third concave part and the fourth concave part may provide a sliding rail for sliding of the second connecting rod in the second sliding slot, so that sliding stability of the second connecting rod can be improved.

When the connecting rod is disposed, a first sliding part and a second sliding part may be respectively disposed on two sides of the first connecting rod in the rotation axial direction of the hinge mechanism, and the first sliding part and the second sliding part may be separately slidably connected to the side wall that is of the first sliding slot and that is in the direction perpendicular to the rotation axial direction of the hinge mechanism. When the first connecting rod slides, the first sliding part and the second sliding part are used as parts of the first connecting rod in contact with the first sliding slot and the first stop block, and the first sliding part and the second sliding part are respectively disposed on the two sides of the first connecting rod in the rotation axial direction of the hinge mechanism, so that overall sliding stability of the first connecting rod can be improved. A thickness of a part of the first connecting rod except the first sliding part and the second sliding part may be appropriately thin, so that an overall weight of the first connecting rod can be reduced, and rotation of the first connecting rod relative to the first housing support may be further allowed to be implemented in a process in which the first connecting rod slides relative to the first housing support. A third sliding part and a fourth sliding part may be respectively disposed on two sides of the second connecting rod in the rotation axial direction of the hinge mechanism, and the third sliding part and the fourth sliding part may be separately slidably connected to the side wall that is of the second sliding slot and that is in the direction perpendicular to the rotation axial direction of the hinge mechanism. When the second connecting rod slides, the third sliding part and the fourth sliding part are used as parts of the second connecting rod in contact with the second sliding slot and the second stop block, and the third sliding part and the fourth sliding part are respectively disposed on the two sides of the second connecting rod in the rotation axial direction of the hinge mechanism, so that stability of overall sliding of the second connecting rod can be improved. A thickness of a part of the second connecting rod except the third sliding part and the fourth sliding part may be appropriately thin, so that an overall weight of the second connecting rod can be reduced, and rotation of the second connecting rod relative to the second housing support may be further allowed to be implemented in a process in which the second connecting rod slides relative to the second housing support.

In a specific implementable solution, a first arc-shaped surface may be provided on an end that is of the first sliding part and that is away from the main shaft, and a second arc-shaped surface may be provided on an end that is of the second sliding part and that is away from the main shaft. When the first connecting rod slides, the first arc-shaped surface is in contact with the first sliding slot and the first stop block, and the second arc-shaped surface is also in contact with the first sliding slot and the first stop block, so that sliding precision and smoothness of the first connecting rod can be ensured. A third arc-shaped surface may be provided on an end that is of the third sliding part and that is away from the main shaft, and a fourth arc-shaped surface may be provided on an end that is of the fourth sliding part and that is away from the main shaft. When the second connecting rod slides, the third arc-shaped surface is in contact with the second sliding slot and the second stop block, and the fourth arc-shaped surface is also in contact with the second sliding slot and the second stop block, so that sliding precision and smoothness of the second connecting rod can be ensured.

In a specific implementable solution, a cross-sectional area of the first sliding part in the rotation axial direction of the hinge mechanism decreases from the end away from the main shaft to an end close to the main shaft, and a cross-sectional area of the second sliding part in the rotation axial direction of the hinge mechanism decreases from the end away from the main shaft to an end close to the main shaft. The first sliding part and the second sliding part are wedge-shaped structures, so that not only sliding precision and smoothness of the first connecting rod can be ensured, but also wear resistance of the sliding part can be improved. Therefore, sliding stability of the first connecting rod and a service life of the first connecting rod can be improved. A cross-sectional area of the third sliding part in the rotation axial direction of the hinge mechanism decreases from the end away from the main shaft to an end close to the main shaft, and a cross-sectional area of the fourth sliding part in the rotation axial direction of the hinge mechanism decreases from the end away from the main shaft to an end close to the main shaft. The third sliding part and the fourth sliding part are wedge-shaped structures, so that not only sliding precision and smoothness of the second connecting rod can be ensured, but also wear resistance of the sliding part can be improved. Therefore, sliding stability of the second connecting rod and a service life of the second connecting rod can be improved.

In a specific implementable solution, a first stop slot may be disposed on the first connecting rod in a sliding direction of the first connecting rod, a first stop protrusion may be disposed on a surface that is of the first stop block and that faces the first connecting rod, and the first stop protrusion may extend into the first stop slot. When the electronic device is unfolded to the flattened state, that the first connecting rod presses against the first stop block includes an end that is of the first stop slot and that is away from the main shaft may press against the first stop protrusion. In this way, the first connecting rod can be restricted from continuously sliding away from the first housing support. In other words, the first housing support and the first connecting rod are restricted from continuously sliding relative to each other in the unfolding direction, so that the first housing support is restricted from continuously rotating relative to the main shaft in the unfolding direction. A second stop slot may be disposed on the second connecting rod in a sliding direction of the second connecting rod, a second stop protrusion may be disposed on a surface that is of the second stop block and that faces the second connecting rod, and the second stop protrusion may extend into the second stop slot. When the electronic device is unfolded to the flattened state, that the second connecting rod presses against the second stop block includes an end that is of the second stop slot and that is away from the main shaft may press against the second stop protrusion. In this way, the second connecting rod can be restricted from continuously sliding away from the second housing support. In other words, the second housing support and the second connecting rod are restricted from continuously sliding relative to each other in the unfolding direction, so that the second housing support is restricted from continuously rotating relative to the main shaft in the unfolding direction.

In a specific implementable solution, a first mounting slot and a second mounting slot may be disposed on the first housing support, the first mounting slot and the second mounting slot may be respectively located on the two sides of the first connecting rod in the rotation axial direction of the hinge mechanism, and two ends of the first stop block in the rotation axial direction of the hinge mechanism may be respectively fastened to the first mounting slot and the second mounting slot. In this way, the first stop block can be fastened to the first housing support. A third mounting slot and a fourth mounting slot may be disposed on the second housing support, the third mounting slot and the fourth mounting slot may be respectively located on the two sides of the second connecting rod in the rotation axial direction of the hinge mechanism, and two ends of the second stop block in the rotation axial direction of the hinge mechanism may be respectively fastened to the third mounting slot and the fourth mounting slot. In this way, the second stop block can be fastened to the second housing support.

In a specific implementable solution, a first gear part may be disposed at an end that is of the first connecting rod and that is rotatably connected to the main shaft, a second gear part may be disposed at an end that is of the second connecting rod and that is rotatably connected to the main shaft, and the first gear part may be in transmission connection to the second gear part, so that the first connecting rod and the second connecting rod may synchronously rotate away from or close to each other relative to the main shaft. In this way, the first connecting rod and the second connecting rod can rotate synchronously relative to the main shaft.

In a specific implementable solution, a synchronization gear group may be disposed on the main shaft, the synchronization gear group may be located between the first connecting rod and the second connecting rod, and the first gear part may be in transmission connection to the second gear part through the synchronization gear group. The synchronization gear group may include an even number of transmission gears that are sequentially in transmission connection to each other. In this way, the first gear part and the second gear part can rotate synchronously, so that the first connecting rod and the second connecting rod rotate synchronously.

According to a second aspect, this disclosure further provides an electronic device, including a first housing, a second housing, a flexible display, and the hinge mechanism according to any one of the implementable solutions of the first aspect. The first housing and the second housing may be respectively disposed on two opposite sides of the hinge mechanism, the first housing may be fastened to the first housing support, and the second housing may be fastened to the second housing support. The flexible display may continuously cover the first housing, the second housing, and the hinge mechanism, and the flexible display may be fastened to the first housing and the second housing.

According to the electronic device provided in this disclosure, the included angle in the flattened state is reliably controlled, the electronic device is not likely to be over-folded, and the flexible display of the electronic device is not likely to be damaged.

### BRIEF DESCRIPTION OF DRAWINGS

FIG. 1 is a diagram of an exploded structure of a hinge mechanism according to an embodiment of this disclosure;

FIG. 2 is a diagram of an assembly structure of a hinge mechanism according to an embodiment of this disclosure;

FIG. 3 is a diagram of a structure of a hinge mechanism in a folded state according to an embodiment of this disclosure;

FIG. 4 is a diagram of a structure of a hinge mechanism in a flattened state according to an embodiment of this disclosure;

FIG. 5 is a diagram of an assembly structure of a partial structure of a hinge mechanism according to an embodiment of this disclosure;

FIG. 6 is a diagram of a structure of a first housing support of a hinge mechanism according to an embodiment of this disclosure;

FIG. 7 is a diagram of a structure of a first stop block of a hinge mechanism according to an embodiment of this disclosure;

FIG. 8 is a diagram of a structure of a hinge mechanism according to another embodiment of this disclosure;

FIG. 9 is a diagram of a partial structure of a hinge mechanism according to another embodiment of this disclosure; and

FIG. 10 is a diagram of a structure of a first connecting rod of a hinge mechanism according to an embodiment of this disclosure.

Reference numerals: 1: main shaft; 2: first housing support; 3: second housing support; 10: first stop structure; 20: second stop structure; 21: first sliding slot; 211: first avoidance slot; 212: first concave part; 213: second concave part; 22: first mounting slot; 23: second mounting slot; 31: second sliding slot; 312: third concave part; 313: fourth concave part; 101: first connecting rod; 102: first stop block; 1011: first sliding part; 1012: second sliding part; 1013: first stop slot; 1014: first mounting hole; 1015: first gear part; 10111: first arc-shaped surface; 10121: second arc-shaped surface; 1021: third sliding slot; 1022: first stop protrusion; 1023: first adjustment slot; 201: second connecting rod; 202: second stop block; and 2015: second gear part.

### DESCRIPTION OF EMBODIMENTS

To make the objectives, technical solutions, and advantages of this disclosure clearer, the following further describes the embodiments of this disclosure in detail with reference to the accompanying drawings. However, example embodiments may be implemented in a plurality of forms and should not be construed as being limited to embodiments described herein. Identical reference numerals in the accompanying drawings denote identical or similar structures. Therefore, repeated description thereof is omitted. Expressions of locations and directions in embodiments of this disclosure are described by using the accompanying drawings as an example. However, changes may also be made as required, and all the changes fall within the protection scope of this disclosure. The accompanying drawings in embodiments of this disclosure are merely used to illustrate relative position relationships and do not represent an actual scale.

Specific details are described in the following description to facilitate understanding of this disclosure. However, embodiments of this disclosure can be implemented in a plurality of manners different from those described herein, and a person skilled in the art may make similar promotion without departing from the connotation of the embodiments of this disclosure. Therefore, this disclosure is not limited to the following disclosed specific implementations.

For ease of understanding, an application scenario of a hinge mechanism in embodiments of this disclosure is first described. The hinge mechanism provided in embodiments of this disclosure may be used in an electronic device, for example, a mobile terminal like a mobile phone, a tablet computer, or a notebook computer. In a possible application scenario, the hinge mechanism provided in embodiments of this disclosure may be used in a foldable electronic device, and is used as a component of a hinge module of the foldable electronic device.

The foldable electronic device usually includes a mechanical part, for example, a flexible display, a hinge module, and a housing. The housing includes a first housing and a second housing that are movably connected through the hinge module. When the entire foldable electronic device is unfolded or folded, the first housing rotates relative to the second housing, the hinge module provides a damping force, and the flexible display is bent.

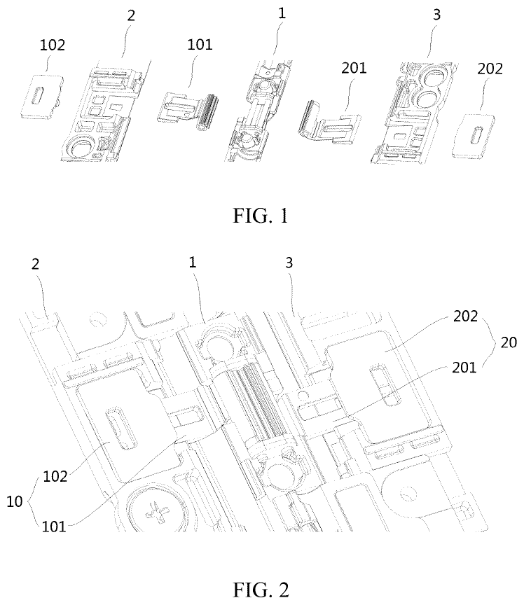

First, FIG. 1 is a diagram of an exploded structure of the hinge mechanism according to an embodiment of this disclosure, and FIG. 2 is a diagram of an assembly structure of the hinge mechanism according to an embodiment of this disclosure. As shown in FIG. 1 and FIG. 2, the hinge mechanism provided in embodiments of this disclosure may include a main shaft 1, a first housing support 2, a second housing support 3, and a flatness stop mechanism. The first housing support 2 and the second housing support 3 may be respectively disposed on two opposite sides of the main shaft 1. The flatness stop mechanism includes two stop structures. The two stop structures are a first stop structure 10 and a second stop structure 20. The first stop structure 10 and the second stop structure 20 may be respectively disposed on two opposite sides of the main shaft 1.

In embodiments of this disclosure, the first stop structure 10 may include a first connecting rod 101 and a first stop block 102. The first connecting rod 101 may be rotatably connected to the main shaft 1, and a rotation axial direction of the first connecting rod 101 may be parallel to a rotation axial direction of the hinge mechanism. The first connecting rod 101 may be simultaneously slidably connected to the first housing support 2. The first stop block 102 may be fastened to the first housing support 2. For example, the first stop block 102 may be welded to the first housing support 2. The first stop block 102 is disposed opposite to the first connecting rod 101. The first stop block 102 is disposed at a location corresponding to the first connecting rod 101.

Similar to the first stop structure 10, the second stop structure 20 may include a second connecting rod 201 and a second stop block 202. The second connecting rod 201 is rotatably connected to the main shaft 1, the second connecting rod 201 is slidably connected to the second housing support 3, and the second stop block 202 is fastened to the second housing support 3. The second stop block 202 is disposed opposite to the second connecting rod 201.

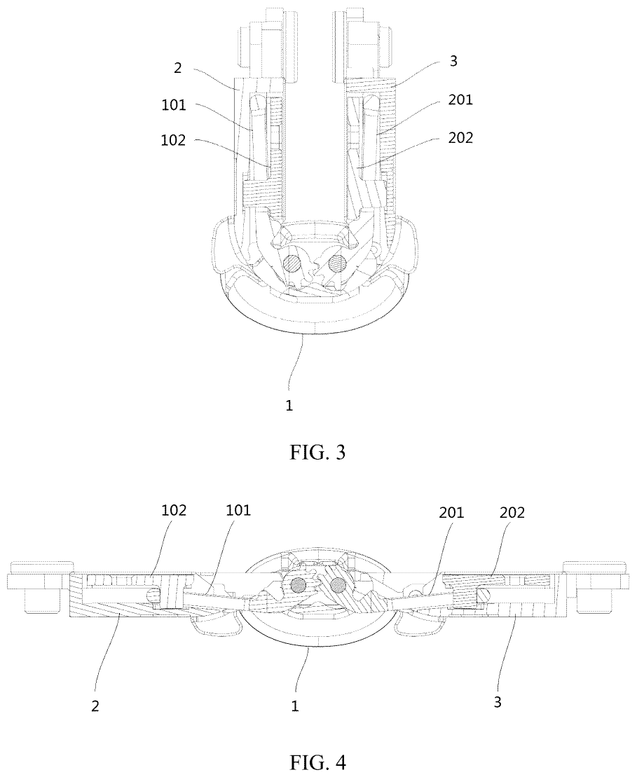

FIG. 3 is a diagram of a structure of the hinge mechanism in a folded state according to an embodiment of this disclosure, and FIG. 4 is a diagram of a structure of the hinge mechanism in a flattened state according to an embodiment of this disclosure. As shown in FIG. 3 and FIG. 4, in specific implementation, the first connecting rod 101 may be in transmission connection to the second connecting rod 201. When the electronic device is unfolded or folded, the first housing support 2 and the second housing support 3 may rotate synchronously away from or close to each other relative to the main shaft 1. The first connecting rod 101 and the second connecting rod 201 may be driven to rotate synchronously away from or close to each other relative to the main shaft 1, the first connecting rod 101 may slide relative to the first housing support 2, and the second connecting rod 201 may slide relative to the second housing support 3. In a process in which the electronic device is unfolded to the flattened state, the first connecting rod 101 slides in a direction away from the first housing support 2, and when the electronic device is unfolded to the flattened state, the first connecting rod 101 presses against the first stop block 102, so that the first connecting rod 101 is restricted from continuously sliding relative to the first housing support 2. In other words, the first connecting rod 101 is prevented from continuously sliding in the direction away from the first housing support 2, so that the first housing support 2 is restricted from continuously rotating in an unfolding direction relative to the main shaft 1. Similarly, the second connecting rod 201 slides in a direction away from the second housing support 3, and when the electronic device is unfolded to the flattened state, the second connecting rod 201 presses against the second stop block 202, so that the second connecting rod 201 is restricted from continuously sliding relative to the second housing support 3. In other words, the second connecting rod 201 is prevented from continuously sliding in the direction away from the second housing support 3, so that the second housing support 3 is restricted from continuously rotating in the unfolding direction relative to the main shaft 1. Rotation of both the first housing support 2 and the second housing support 3 in the unfolding direction is restricted in the flattened state, so that an included angle of the electronic device in the flattened state can be reliably controlled, the electronic device is not likely to be over-folded, and the flexible display of the electronic device is not likely to be damaged. In addition, in an assembly process, a relative location of the first stop block 102 on the first housing support 2 and a relative location of the second stop block 202 on the second housing support 3 may be adjusted, so that an included angle between the first housing support 2 and the second housing support 3 in the flattened state may be adjusted. In other words, the included angle of the electronic device in the flattened state is adjusted, so that fitting tolerance between covered components is easily adjusted, and an ideal included angle in the flattened state is easily achieved.

For ease of description, in the following embodiments of this disclosure, a specific disposing manner of the first stop structure 10 is mainly used as an example to describe the hinge mechanism, and the second stop structure 20 may be disposed with reference to the first stop structure 10. It may be understood that a design of the second stop structure 20 may be completely the same as that of the first stop structure 10, or for a design of the second stop structure 20, reference may be made only to components and connection relationships included in the first stop structure 10, other parameters may be adaptively adjusted, and the design of the second stop structure 20 does not need to be completely the same as that of the first stop structure 10.

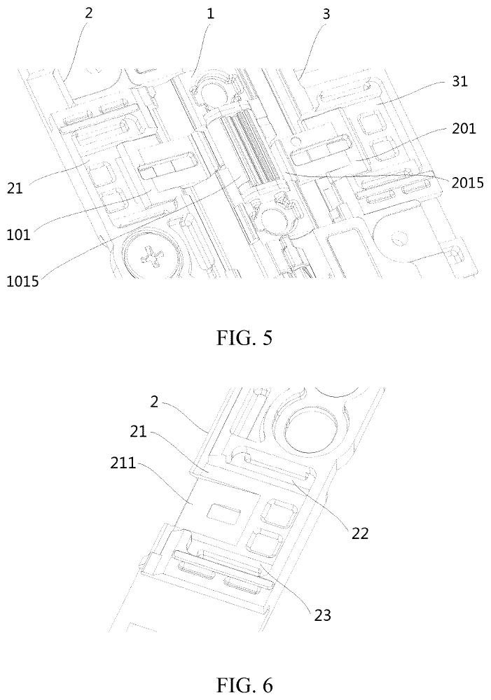

FIG. 5 is a diagram of an assembly structure of a partial structure of the hinge mechanism according to an embodiment of this disclosure, and FIG. 6 is a diagram of a structure of the first housing support of the hinge mechanism according to an embodiment of this disclosure. Different from that in FIG. 2, the first stop block 102 and the second stop block 202 in FIG. 2 are not shown in FIG. 5. As shown in FIG. 5, in embodiments of this disclosure, a first sliding slot 21 is disposed on the first housing support 2, and the first sliding slot 21 extends in a direction away from the main shaft 1. For example, the hinge mechanism is used in an electronic device that is folded inward. Further, the first sliding slot 21 may be located on a surface that is of the first housing support 2 and that faces the flexible display. When the first housing support 2 is molded by using a mold, the first sliding slot 21 may be molded together by using the mold. The first connecting rod 101 may be slidably disposed in the first sliding slot 21, so that the first connecting rod 101 is slidably connected to the first housing support 2. When the electronic device is unfolded or folded, the first housing support 2 rotates relative to the main shaft 1 in the direction away from the main shaft 1 or a direction close to the main shaft 1, and drives the first connecting rod 101 to rotate relative to the main shaft 1 in the direction away from the main shaft 1 or the direction close to the main shaft 1. Simultaneously, the first connecting rod 101 slides relative to the first housing support 2 in a direction away from the first housing support 2 or a direction close to the first housing support 2.

As shown in FIG. 6, a first avoidance slot 211 may be disposed in the first sliding slot 21, and the first avoidance slot 211 may be disposed on a side wall that is of the first sliding slot 21 and that is in a direction perpendicular to a rotation axial direction of the hinge mechanism. As shown in FIG. 5, the first avoidance slot 211 may provide avoidance space for rotation that is of the first connecting rod 101 relative to the first housing support 2 and that may exist in a process in which the first connecting rod 101 slides relative to the first housing support 2, to avoid interference to sliding of the first connecting rod 101.

As shown in FIG. 2 and FIG. 6, a first opening may be disposed in the first sliding slot 21 in the direction perpendicular to the rotation axial direction of the hinge mechanism. For example, when the hinge mechanism is used in an electronic device that is folded inward, the first opening may face the flexible display. The first stop block 102 may cover the first opening. A part of the first connecting rod 101 may be located between the first stop block 102 and the first housing support 2. In other words, a part of the first connecting rod 101 may be located in accommodation space formed by the first stop block 102 and the first sliding slot 21, and the first stop block 102 and the first housing support 2 clamp a part of the first connecting rod 101. The first stop block 102 may enable the first connecting rod 101 to be stably maintained in the first sliding slot 21, so that the first connecting rod 101 is prevented from shaking in the direction perpendicular to the rotation axial direction of the hinge mechanism, and sliding stability and smoothness of the first connecting rod 101 is improved. In this specific implementation, when the electronic device is unfolded to the flattened state, the first stop block 102 has a function of restricting the first connecting rod 101 to continue sliding relative to the first housing support 2. In addition, the first stop block 102 further has a function of clamping a part of the first connecting rod 101 together with the first housing support 2, to prevent the first connecting rod 101 from shaking in the direction perpendicular to the rotation axial direction of the hinge mechanism.

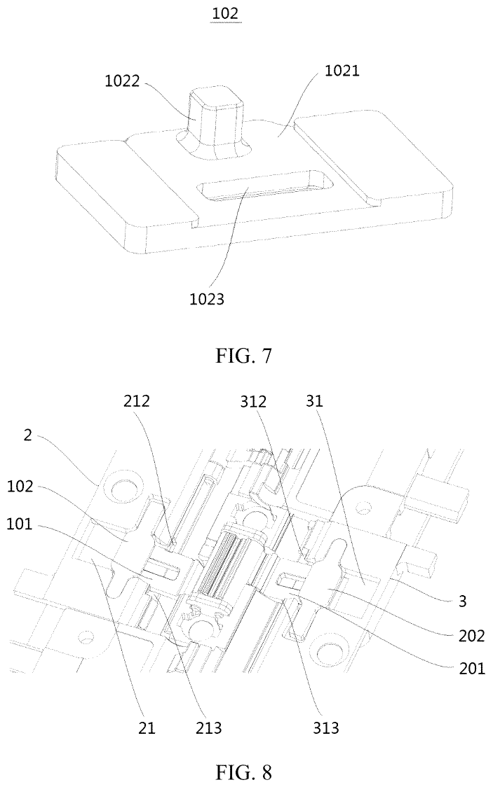

FIG. 7 is a diagram of a structure of the first stop block of the hinge mechanism according to an embodiment of this disclosure. As shown in FIG. 5 and FIG. 7, a third sliding slot 1021 may be disposed on a surface that is of the first stop block 102 and that faces the first connecting rod 101. The third sliding slot 1021 and the first sliding slot 21 may be aligned in the direction perpendicular to the rotation axial direction of the hinge mechanism, and the third sliding slot 1021 and the first sliding slot 21 jointly form accommodation space, to accommodate a part of the first connecting rod 101. The third sliding slot 1021 may share a part of a depth of the accommodation space in the direction perpendicular to the rotation axial direction of the hinge mechanism, so that a depth of the first sliding slot 21 may be shallow. This helps maintain structural strength of the first housing support 2.

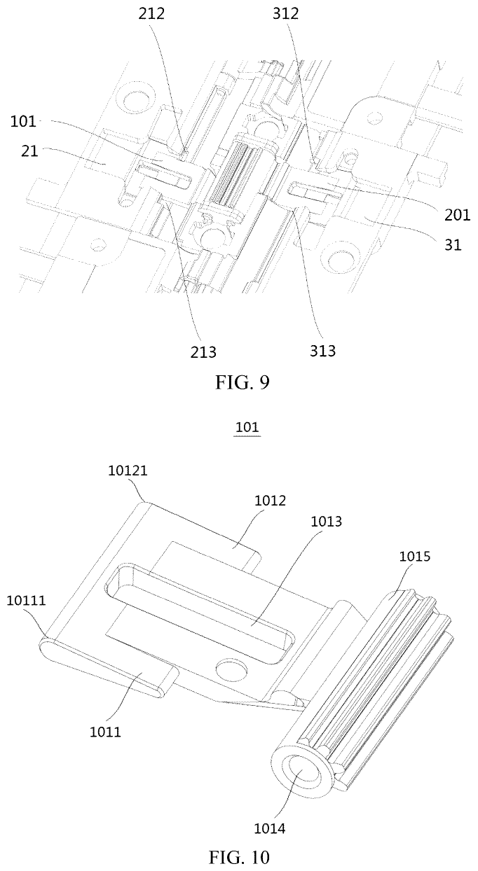

FIG. 8 is a diagram of a structure of a hinge mechanism according to another embodiment of this disclosure, and FIG. 9 is a diagram of a partial structure of a hinge mechanism according to another embodiment of this disclosure. Different from that in FIG. 5, a structure of a first sliding slot 21 in FIG. 8 is changed. Different from that in FIG. 8, the first stop block 102 and the second stop block 202 in FIG. 8 are not shown in FIG. 9. As shown in FIG. 8, a first concave part 212 and a second concave part 213 may be disposed in the first sliding slot 21. The first concave part 212 and the second concave part 213 are respectively disposed on two side walls that are of the first sliding slot 21 and that are opposite to each other in a rotation axial direction of a hinge mechanism. A first connecting rod 101 may be slidably connected to the first concave part 212 and the second concave part 213. The first concave part 212 and the second concave part 213 may provide a sliding rail for sliding of the first connecting rod 101 in the first sliding slot 21, so that sliding stability of the first connecting rod 101 can be improved. Further, the first concave part 212 and the second concave part 213 may be formed in the first sliding slot 21 in a slot digging manner. In this specific implementation, when an electronic device is unfolded to a flattened state, the first stop block 102 has a function of restricting the first connecting rod 101 to continue sliding relative to the first housing support 2. The first concave part 212 and the second concave part 213 have a function of restricting the first connecting rod 101 to shake in a direction perpendicular to a rotation axial direction of the hinge mechanism.

FIG. 10 is a diagram of a structure of the first connecting rod of the hinge mechanism according to an embodiment of this disclosure. As shown in FIG. 5, FIG. 8, and FIG. 10, a first mounting hole 1014 may be disposed at an end that is of the first connecting rod 101 and that is rotatably connected to the main shaft 1. The first connecting rod 101 may be rotatably connected to the main shaft 1 through a connecting piece like a pin shaft that penetrates into the first mounting hole 1014. A first sliding part 1011 and a second sliding part 1012 may be respectively disposed on two sides of the first connecting rod 101 in the rotation axial direction of the hinge mechanism, and the first sliding part 1011 and the second sliding part 1012 may be separately slidably connected to a side wall that is of the first sliding slot 21 and that is in the direction perpendicular to the rotation axial direction of the hinge mechanism. When the first connecting rod 101 slides, the first sliding part 1011 and the second sliding part 1012 are used as parts of the first connecting rod 101 in contact with the first sliding slot 21 and the first stop block 102, and the first sliding part 1011 and the second sliding part 1012 are respectively disposed on the two sides of the first connecting rod 101 in the rotation axial direction of the hinge mechanism, so that overall sliding stability of the first connecting rod 101 can be improved. A thickness of a part of the first connecting rod 101 except the first sliding part 1011 and the second sliding part 1012 may be appropriately thin, so that an overall weight of the first connecting rod 101 can be reduced, and rotation of the first connecting rod 101 relative to the first housing support 2 may be further allowed to be implemented in a process in which the first connecting rod 101 slides relative to the first housing support 2. Further, when the first concave part 212 and the second concave part 213 are disposed in the first sliding slot 21, the first sliding part 1011 and the second sliding part 1012 may be respectively located in the first concave part 212 and the second concave part 213. The first sliding part 1011 may be slidably connected to a side wall that is of the first concave part 212 and that is in the direction perpendicular to the rotation axial direction of the hinge mechanism, and the second sliding part 1012 may be slidably connected to a side wall that is of the second concave part 213 and that is in the direction perpendicular to the rotation axial direction of the hinge mechanism, so that overall sliding stability of the first connecting rod 101 can be further improved.

In embodiments of this disclosure, a first arc-shaped surface 10111 may be provided on an end that is of the first sliding part 1011 and that is away from the main shaft 1, and an axial direction of the first arc-shaped surface 10111 may be parallel to the rotation axial direction of the hinge mechanism. A second arc-shaped surface 10121 may be provided on an end that is of the second sliding part 1012 and that is away from the main shaft 1, and an axial direction of the second arc-shaped surface 10121 may also be parallel to the rotation axial direction of the hinge mechanism. When the first connecting rod 101 slides, the first arc-shaped surface 10111 is in contact with the first sliding slot 21 and the first stop block 102, and the second arc-shaped surface 10121 is also in contact with the first sliding slot 21 and the first stop block 102, so that sliding precision and smoothness of the first connecting rod 101 can be ensured. During specific implementation, the first arc-shaped surface 10111 and the second arc-shaped surface 10121 may extend in the rotation axial direction of the hinge mechanism to form a complete arc-shaped surface, so that molding is facilitated.

In some possible specific implementations, the first sliding part 1011 may be of a cylindrical structure, and the first arc-shaped surface 10111 is a part of a cylindrical surface of the first sliding part 1011. Similarly, the second sliding part 1012 may also be of a cylindrical structure, and the second arc-shaped surface 10121 is a part of a cylindrical surface of the second sliding part 1012. In some other possible specific implementations, a cross-sectional area of the first sliding part 1011 in the rotation axial direction of the hinge mechanism decreases from the end away from the main shaft 1 to an end close to the main shaft 1. This may be understood as that the first sliding part 1011 is of a wedge-shaped structure, and two ends of the wedge-shaped structure may separately have an arc-shaped surface. A cross-sectional area of the second sliding part 1012 in the rotation axial direction of the hinge mechanism decreases from the end away from the main shaft 1 to an end close to the main shaft 1. Similarly, this may be understood as that the second sliding part 1012 is of a wedge-shaped structure, and two ends of the wedge-shaped structure may also separately have an arc-shaped surface. The wedge-shaped sliding part can not only ensure sliding precision and smoothness of the first connecting rod 101, but also improve wear resistance of the sliding part. Therefore, sliding stability of the first connecting rod 101 and a service life of the first connecting rod 101 can be improved.

As shown in FIG. 7, a first stop slot 1013 may be disposed on the first connecting rod 101 in a sliding direction of the first connecting rod 101. A first stop protrusion 1022 may be disposed on a surface that is of the first stop block 102 and that faces the first connecting rod 101. During actual assembly, the first stop protrusion 1022 extends into the first stop slot 1013. When the electronic device is unfolded to the flattened state, the first connecting rod 101 presses against the first stop block 102. Further, an end that is of the first stop slot 1013 and that is away from the main shaft 1 presses against the first stop protrusion 1022, so that the first connecting rod 101 is restricted from continuously sliding away from the first housing support 2. In other words, the first housing support 2 and the first connecting rod 101 are restricted from continuously sliding relative to each other in an unfolding direction, so that the first housing support 2 is restricted from continuously rotating relative to the main shaft 1 in the unfolding direction. During specific implementation, the first stop slot 1013 may be a circumferentially closed slot, or may be a circumferentially unclosed half-open slot, as long as the first stop slot 1013 can perform the foregoing restricting functions.

As shown in FIG. 2 and FIG. 6, a first mounting slot 22 and a second mounting slot 23 may be disposed on the first housing support 2. For example, when the hinge mechanism is used in an electronic device that is folded inward, the first mounting slot 22 and the second mounting slot 23 may be located on a surface that is of the first housing support 2 and that faces the flexible display, and the first mounting slot 22 and the second mounting slot 23 may be respectively located on two sides of the first connecting rod 101 in the rotation axial direction of the hinge mechanism. Two ends of the first stop block 102 in the rotation axial direction of the hinge mechanism may be respectively fastened to the first mounting slot 22 and the second mounting slot 23, so that the first stop block 102 is fastened to the first housing support 2.

As shown in FIG. 7, during specific implementation, a first adjustment slot 1023 may be disposed on the first stop block 102, so that a relative location between the first stop block 102 and the first housing support 2 is adjusted in an assembly process, and a weight of the first stop block 102 can be appropriately reduced.

As described above, the second housing support 3 and the first housing support 2 may be respectively disposed on two opposite sides of the main shaft 1. During specific implementation, as shown in FIG. 5, a second sliding slot 31 is disposed on the second housing support 3. The second sliding slot 31 extends in a direction away from the main shaft 1. The second connecting rod 201 is slidably disposed in the second sliding slot 31. When the electronic device is unfolded or folded, the second connecting rod 201 slides relative to the second housing support 3 in a direction away from the second housing support 3 or a direction close to the second housing support 3.

In embodiments of this disclosure, a second avoidance slot is disposed in the second sliding slot 31, and the second avoidance slot is disposed on a side wall that is of the second sliding slot 31 and that is in the direction perpendicular to the rotation axial direction of the hinge mechanism. As shown in FIG. 2, a second opening is disposed in the second sliding slot 31 in the direction perpendicular to the rotation axial direction of the hinge mechanism, the second stop block 202 covers the second opening, and a part of the second connecting rod 201 is located between the second stop block 202 and the second housing support 3.

In specific implementation, a fourth sliding slot is disposed on a surface that is of the second stop block 202 and that faces the second connecting rod 201, the fourth sliding slot and the second sliding slot 31 are aligned in the direction perpendicular to the rotation axial direction of the hinge mechanism, and the fourth sliding slot and the second sliding slot 31 jointly form accommodation space, to accommodate the second connecting rod 201.

In embodiments of this disclosure, as shown in FIG. 8, a third concave part 312 and a fourth concave part 313 are disposed in the second sliding slot 31. The third concave part 312 and the fourth concave part 313 are respectively disposed on two side walls that are of the second sliding slot 31 and that are opposite to each other in the rotation axial direction of the hinge mechanism, and the second connecting rod 201 is slidably connected to the third concave part 312 and the fourth concave part 313.

In embodiments of this disclosure, a third sliding part and a fourth sliding part are respectively disposed on two sides of the second connecting rod 201 in the rotation axial direction of the hinge mechanism, and the third sliding part and the fourth sliding part may be separately slidably connected to a side wall that is of the second sliding slot 31 and that is in the direction perpendicular to the rotation axial direction of the hinge mechanism. A third arc-shaped surface is provided on an end that is of the third sliding part and that is away from the main shaft 1, and a fourth arc-shaped surface is provided on an end that is of the fourth sliding part and that is away from the main shaft 1. A cross-sectional area of the third sliding part in the rotation axial direction of the hinge mechanism decreases from the end away from the main shaft 1 to an end close to the main shaft 1. This may be understood as that the third sliding part is of a wedge-shaped structure. A cross-sectional area of the fourth sliding part in the rotation axial direction of the hinge mechanism decreases from the end away from the main shaft 1 to an end close to the main shaft 1. This may be understood as that the fourth sliding part is of a wedge-shaped structure.

In embodiments of this disclosure, a second stop slot is disposed on the second connecting rod 201 in a sliding direction of the second connecting rod 201, a second stop protrusion is disposed on a surface that is of the second stop block 202 and that faces the second connecting rod 201, and the second stop protrusion extends into the second stop slot. When the electronic device is unfolded to the flattened state, an end that is of the second stop slot and that is away from the main shaft 1 may press against the second stop protrusion.

In embodiments of this disclosure, a third mounting slot and a fourth mounting slot are disposed on the second housing support 3, the third mounting slot and the fourth mounting slot are respectively located on the two sides of the second connecting rod 201 in the rotation axial direction of the hinge mechanism, and two ends of the second stop block 202 in the rotation axial direction of the hinge mechanism are respectively fastened to the third mounting slot and the fourth mounting slot.

It may be understood that some features in the foregoing embodiments are described by using an example in which the hinge mechanism is used in an electronic device that is folded inward. In actual application, the hinge mechanism may alternatively be used in an electronic device that is folded outward. In this case, a setting location, an orientation, and the like of these features may be adaptively adjusted based on a change of a folding direction of the electronic device.

As shown in FIG. 5 and FIG. 10, a first gear part 1015 may be disposed at an end that is of the first connecting rod 101 and that is rotatably connected to the main shaft 1, and a second gear part 2015 may be disposed at an end that is of the second connecting rod 201 and that is rotatably connected to the main shaft 1. The first gear part 1015 is in transmission connection to the second gear part 2015, so that the first connecting rod 101 and the second connecting rod 201 rotate synchronously away from or close to each other relative to the main shaft 1. Further, the first gear part 1015 may include a plurality of first gear structures disposed around the rotation axial direction of the first connecting rod 101, and the second gear part 2015 may include a plurality of second gear structures disposed around a rotation axial direction of the second connecting rod 201. The first gear part 1015 meshes with the second gear part 2015 based on the plurality of first gear structures and the plurality of second gear structures, so that the first gear part 1015 rotates synchronously with the second gear part 2015.

In specific implementation, a synchronization gear group may be disposed on the main shaft 1, the synchronization gear group may be located between the first connecting rod 101 and the second connecting rod 201, and the first gear part 1015 may be in transmission connection to the second gear part 2015 through the synchronization gear group. The synchronization gear group may include an even number of transmission gears that are sequentially in transmission connection to each other. For example, the synchronization gear group includes two transmission gears that are sequentially in rotational connection to each other, so that the first gear part 1015 rotates synchronously with the second gear part 2015, and the first connecting rod 101 rotates synchronously with the second connecting rod 201. Further, an axial direction of the transmission gear may be parallel to the rotation axial direction of the hinge mechanism.

The foregoing descriptions are merely specific implementations of this disclosure, but are not intended to limit the protection scope of this disclosure. Any variation or replacement readily figured out by a person skilled in the art within the technical scope disclosed in this disclosure shall fall within the protection scope of this disclosure.

1. A hinge mechanism configured to dispose opposite to a foldable part of a flexible display of a foldable electronic device, configured to unfold or fold the foldable electronic device and comprising:
a main shaft comprising:
a first side; and
a second side opposite to the first side;
a first housing support disposed on the first side;
a second housing support disposed on the second side, wherein the first housing support and the second housing support are configured to rotate synchronously away from or toward each other relative to the main shaft while the foldable electronic device is unfolded or folded; and
a flatness stop mechanism comprising:
a first stop structure comprising:
a first connecting rod rotatably coupled to the main shaft, slidably coupled to the first housing support, and configured to:
slide relative to the first housing support while the foldable electronic device is unfolded or folded; and
slide in a first direction away from the first housing support while the foldable electronic device is changing from an unfolded state to a flattened state; and
a first stop block fastened to the first housing support and disposed opposite to the first connecting rod; and
a second stop structure comprising:
a second connecting rod rotatably coupled to the main shaft, slidably coupled to the second housing support, further coupled to the first connecting rod in a first transmission connection manner, and configured to:
slide relative to the second housing support while the foldable electronic device is unfolded or folded;
rotate synchronously away from or toward with the first connecting rod relative to the main shaft while the foldable electronic device is unfolded or folded; and
slide in a second direction away from the second housing support while the foldable electronic device is changing from the unfolded state to the flattened state; and
a second stop block is fastened to the second housing support and disposed opposite to the second connecting rod wherein the first connecting rod is further configured to press against the first stop block and the second connecting rod is further configured to press against the second stop block when the foldable electronic device is in the flattened state.

2. The hinge mechanism of claim 1, further comprising:
a first sliding slot disposed on the first housing support and extending in a third direction away from the main shaft, wherein the first connecting rod is slidably disposed in the first sliding slot and is further configured to slide relative to the first housing support in the first direction or a fourth direction towards the first housing support while the foldable electronic device is unfolded or folded; and
a second sliding slot is disposed on the second housing support and extending in a fifth direction away from the main shaft, wherein the second connecting rod is slidably disposed in the second sliding slot and is further configured to slide relative to the second housing support in the second direction or a sixth direction towards the second housing support while the foldable electronic device is unfolded or folded.

3. The hinge mechanism of claim 2, wherein the first sliding slot comprises a first side wall located in a seventh direction perpendicular to a rotation axial direction of the hinge mechanism, wherein the second sliding slot comprises a second side wall located in the seventh direction, and wherein the hinge mechanism further comprises:
a first avoidance disposed in the first sliding slot and on the first side wall; and
a second avoidance slot disposed in the second sliding slot and on the second side wall.

4. The hinge mechanism of claim 2, further comprising:
a first opening disposed in the first sliding slot in a seventh direction perpendicular to a rotation axial direction of the hinge mechanism, wherein the first stop block is configured to cover the first opening; and
a second opening is disposed in the second sliding slot in the seventh direction, wherein the second stop block is configured to cover the second opening,
wherein a first part of the first connecting rod is located between the first stop block and the first housing support, and
wherein a second part of the second connecting rod is located between the second stop block and the second housing support.

5. The hinge mechanism of claim 2, wherein the first sliding slot comprises:
a first side wall located in a third side of a rotation axial direction of the hinge mechanism; and
a second side wall located in a fourth side of the rotation axial direction, wherein the fourth side is opposite to the third side,
wherein the second sliding slot comprises:
a third side wall located in a fifth side of the rotation axial direction; and
a fourth side wall located in a sixth side of the rotation axial direction, wherein the fifth side is opposite to the sixth side, and
wherein the hinge mechanism further comprises:
a first concave part disposed in the first sliding slot and on the first side wall;
a second concave part disposed in the first sliding slot and on the second side wall, wherein the first connecting rod is slidably coupled to the first concave part and the second concave part;
a third concave part disposed in the second sliding slot and on the third side wall; and
a fourth concave part disposed in the second sliding slot and on the fourth side wall, wherein the second connecting rod is slidably coupled to the third concave part and the fourth concave part.

6. The hinge mechanism of claim 3, wherein the first connecting rod comprises:
a third side; and
a fourth side opposite to the third side,
wherein the second connecting rod comprises:
a fifth side; and
a sixth side opposite to the fourth side,
wherein the hinge mechanism further comprises:
a first sliding part disposed on the third side in the rotation axial direction and slidably coupled to the first side wall;
a second sliding part disposed on the fourth side in the rotation axial direction and slidably coupled to the first side wall;
a third sliding part disposed on the fifth side in the rotation axial direction and slidably coupled to the second side wall; and
a fourth sliding part disposed on the sixth side in the rotation axial direction and slidably coupled to the second side wall.

7. The hinge mechanism of claim 6, wherein the first sliding part comprises a first end located away from the main shaft, wherein the second sliding part comprises a second end located away from the main shaft, wherein the third sliding part comprises a third end located away from the main shaft, wherein the fourth sliding part comprises a fourth end located away from the main shaft, and wherein the hinge mechanism further comprises:
a first arc-shaped surface provided on the first end;
a second arc-shaped surface provided on the second end;
a third arc-shaped surface provided on the third end; and
a fourth arc-shaped surface provided on the fourth end.

8. The hinge mechanism of claim 7, wherein the first sliding part further comprises a fifth end located proximate to the main shaft, wherein the second sliding part further comprises a sixth end located proximate to the main shaft, wherein the third sliding part further comprises a seventh end located proximate to the main shaft, wherein the fourth sliding part further comprises an eighth end located proximate to the main shaft, wherein a first cross-sectional area of the first sliding part decreases from the first end to the fifth end, wherein a second cross-sectional area of the second sliding part decreases from the second end to the sixth end, wherein a third cross-sectional area of the third sliding part decreases from the third end to the seventh end, and wherein a fourth cross-sectional area of the fourth sliding part decreases from the fourth end to the eighth end.

9. The hinge mechanism of claim 4, wherein the first stop block comprises a first surface facing the first connecting rod, wherein the second stop block comprises a second surface facing the second connecting rod, wherein the hinge mechanism further comprises:
a first stop slot disposed on the first connecting rod in a first sliding direction of the first connecting rod and comprising a first end located away from the main shaft;
a first stop protrusion disposed on the first surface and extending into the first stop slot;
a second stop slot disposed on the second connecting rod in a second sliding direction of the second connecting rod and comprising a second end located away from the main shaft; and
a second stop protrusion disposed on the second surface and extending into the second stop slot, and
wherein when the foldable electronic device is in the flattened state:
the first end is configured to press against the first stop protrusion, and the second end is configured to press against the second stop protrusion.

10. The hinge mechanism of claim 1, wherein the first connecting rod comprises a third side and a fourth side, wherein the first stop block comprises a first end and a second end, wherein the second connecting rod comprises a fifth side and a sixth side, wherein the second stop block comprises a third end and a fourth end, and wherein the hinge mechanism further comprises:
a first mounting slot disposed on the first housing support, located on the third side in a rotation axial direction of the hinge mechanism, and fastened to the first end;
a second mounting slot disposed on the first housing support, located on the fourth side in the rotation axial direction, and fastened to the second end;
a third mounting slot disposed on the second housing support, located on the fifth side in the rotation axial direction, and fastened to the third end; and
a fourth mounting slot disposed on the second housing support, located on the sixth side in the rotation axial direction, and fastened to the fourth end.

11. The hinge mechanism of claim 1, wherein the first connecting rod comprises a first end rotatably coupled to the main shaft, wherein the second connecting rod comprises a second end rotatably coupled to the main shaft, and wherein the hinge mechanism further comprises:
a first gear part disposed at the first end; and
a second gear part disposed at the second end,
wherein the first gear part is configured to be in a second transmission connection manner with the second gear part to cause the first connecting rod and the second connecting rod to synchronously rotate away from or toward each other relative to the main shaft.

12. The hinge mechanism of claim 11, further comprising a synchronization gear group disposed on the main shaft, located between the first connecting rod and the second connecting rod configured to couple the first gear part to the second gear part in a third transmission connection manner, and comprising an even number of transmission gears that are sequentially coupled in a fourth transmission connection manner to each other.

13. An electronic device comprising:
a hinge mechanism comprising:
a main shaft, comprising:
a first side; and
a second side opposite to the first side;
a first housing support disposed on the first side;
a second housing support disposed on the second side, wherein the first housing support and the second housing support are configured to rotate synchronously away from or toward each other relative to the main shaft while the electronic device is unfolded or folded; and
a flatness stop mechanism comprising:
a first stop structure comprising:
a first connecting rod rotatably coupled to the main shaft, slidably coupled to the first housing support, and configured to:
slide relative to the first housing support while the electronic device is unfolded or folded;
slide in a first direction away from the first housing support while the electronic device is changing from an unfolded state to a flattened state; and
a first stop block fastened to the first housing support and disposed opposite to the first connecting rod; and
a second stop structure comprising:
a second connecting rod rotatably coupled to the main shaft, slidably coupled to the second housing support, further coupled to the first connecting rod in a first transmission connection manner, and configured to:
slide relative to the second housing support while the electronic device is unfolded or folded;
rotate synchronously away from or toward with the first connecting rod relative to the main shaft while the electronic device is unfolded or folded; and
slide in a second direction away from the second housing support while the electronic device is changing from the unfolded state to the flattened state; and
a second stop block is fastened to the second housing support and disposed opposite to the second connecting rod,
wherein
the first connecting rod is further configured to press against the first stop block, and the second connecting rod is further configured to press against the second stop block when the electronic device is in the flattened state;
a first housing fastened to the first housing support;
a second housing fastened to the second housing support; and
a flexible display fastened to the first housing and the second housing, configured to continuously cover the first housing, the second housing, and the hinge mechanism, and comprising a foldable part,
wherein the hinge mechanism is disposed opposite to the foldable part.

14. The electronic device of claim 13, wherein the hinge mechanism further comprises:
a first sliding slot disposed on the first housing support and extending in a third direction away from the main shaft, wherein the first connecting rod is slidably disposed in the first sliding slot and is further configured to slide relative to the first housing support in the first direction or a fourth direction towards the first housing support while the electronic device is unfolded or folded; and
a second sliding slot disposed on the second housing support and extending in a fifth direction away from the main shaft, wherein the second connecting rod is slidably disposed in the second sliding slot and is further configured to slide relative to the second housing support in the second direction or a sixth direction towards the second housing support while the electronic device is unfolded or folded.

15. The electronic device of claim 14, wherein the first sliding slot comprises a first side wall located in a seventh direction perpendicular to a rotation axial direction of the hinge mechanism, wherein the second sliding slot comprises a second side wall located in the seventh direction, and wherein the hinge mechanism further comprises:
a first avoidance slot disposed in the first sliding slot and on the first side wall; and
a second avoidance slot disposed in the second sliding slot and on the second side wall.

16. The electronic device of claim 14, wherein the hinge mechanism further comprises:
a first opening disposed in the first sliding slot in a seventh direction perpendicular to a rotation axial direction of the hinge mechanism, wherein the first stop block is configured to cover the first opening; and
a second opening disposed in the second sliding slot in the seventh direction, wherein the second stop block is configured to cover the second opening,
wherein a first part of the first connecting rod is located between the first stop block and the first housing support, and
wherein a second part of the second connecting rod is located between the second stop block and the second housing support.

17. The electronic device of claim 14, wherein the first sliding slot comprises:
a first side wall located in a third side of a rotation axial direction of the hinge mechanism; and
a second side wall located in a fourth side of the rotation axial direction, wherein the fourth side is opposite to the third side,
wherein the second sliding slot comprises:
a third side wall located in a fifth side of the rotation axial direction; and
a fourth side wall located in a sixth side of the rotation axial direction, wherein the fifth side is opposite to the sixth side, and
wherein the hinge mechanism further comprises:
a first concave part disposed in the first sliding slot and on the first side wall;
a second concave part disposed in the first sliding slot and on the second side wall, wherein the first connecting rod is slidably coupled to the first concave part and the second concave part
a third concave part disposed in the second sliding slot and on the third side wall; and
a fourth concave part disposed in the second sliding slot and on the fourth side wall, wherein the second connecting rod is slidably coupled to the third concave part and the fourth concave part.

18. The electronic device of claim 15, wherein the first connecting rod comprises:
a third side; and
a fourth side opposite to the third side,
wherein the second connecting rod comprises:
a fifth side; and
a sixth side opposite to the fourth side,
wherein the hinge mechanism further comprises:
a first sliding part disposed on the third side in the rotation axial direction and slidably coupled to the first side wall;
a second sliding part disposed on the fourth side in the rotation axial direction and slidably coupled to the first side wall;
a third sliding part disposed on the fifth side in the rotation axial direction and slidably coupled to the second side wall; and
a fourth sliding part disposed on the sixth side in the rotation axial direction and slidably coupled to the second side wall.

19. The electronic device of claim 18, wherein the first sliding part comprises a first end located away from the main shaft, wherein the second sliding part comprises a second end located away from the main shaft, wherein the third sliding part comprises a third end located away from the main shaft, wherein the fourth sliding part comprises a fourth end located away from the main shaft, and wherein the hinge mechanism further comprises:
a first arc-shaped surface provided on the first end;
a second arc-shaped surface provided on the second end;
a third arc-shaped surface provided on the third end; and
a fourth arc-shaped surface provided on the fourth end.

20. The electronic device of claim 19, wherein the first sliding part further comprises a fifth end located proximate to the main shaft, wherein the second sliding part further comprises a sixth end located proximate to the main shaft, wherein the third sliding part further comprises a seventh end located proximate to the main shaft, wherein the fourth sliding part further comprises an eighth end located proximate to the main shaft, wherein a first cross-sectional area of the first sliding part decreases from the first end to the fifth end, wherein a second cross-sectional area of the second sliding part decreases from the second end to the sixth end, wherein a third cross-sectional area of the third sliding part decreases from the third end to the seventh end, and wherein a fourth cross-sectional area of the fourth sliding part decreases from the fourth end to the eighth end.
